(19) United States
(12) Patent Application Publication
(10) Pub. No.: US 2026/0291400 A1
(43) Pub. Date: Sep. 24, 2026

(54) POWER CONVERSION DEVICE AND ELECTRIC VEHICLE

(71) Applicant: Mitsubishi Electric Mobility Corporation, Tokyo (JP)

(72) Inventors: Seiya EBIHARA, Tokyo (JP); Kazuhiro FUJIOKA, Tokyo (JP)

(73) Assignee: Mitsubishi Electric Mobility Corporation, Tokyo (JP)

(21) Appl. No.: 19/480,091

(22) PCT Filed: Jun. 6, 2023
(86) PCT No.: PCT/JP2023/020929

§ 371 Date: Oct. 30, 2025

(51) Int. Cl. H02M 7/00; B60L 15/00; H02G 5/02; H02M 1/00; H05K 1/11

(52) U.S. Cl. CPC H02M 7/003; H02G 5/02; H02M 1/0009; H05K 1/115; B60L 15/007

(57) ABSTRACT

In a power conversion device, provided are a substrate having one or more through holes, a bus bar connected to a power module and disposed to face the substrate, a core surrounding the bus bar, having a prismatic body with a notch portion, and including a pair of protruding portions formed along the notch portion, and a magnetoelectric conversion element disposed on the substrate. At least one of the pair of protruding portions of the core is inserted into the one or more through holes and fixed to the substrate, and the magnetoelectric conversion element is disposed in either the notch portion of the core or a clearance between the pair of protruding portions of the core.

### TECHNICAL FIELD

The present application relates to a power conversion device and an electric vehicle.

### BACKGROUND ART

A plurality of power conversion devices are mounted on an electric vehicle such as an electric automobile or a hybrid electric automobile in which a motor is used as a driving source. The power conversion device is used for driving a motor, regenerating driving energy to a battery, or the like. Specific examples of the power conversion device include a charger that converts commercial AC power into DC power and charges a high-voltage battery with the DC power, a DC/DC converter that converts DC power of the high-voltage battery into a voltage (for example, 12V) of a battery for an auxiliary device, an inverter that converts the DC power from a battery into AC power for a motor, and other similar devices.

In addition to an element for switching a large current and an arithmetic circuit for controlling a power conversion function, a current sensor for measuring a current flowing through a bus bar and the like are provided inside the power conversion device. Since the power conversion device includes many electric components inside thereof, a problem arises in that the size of the power conversion device is increased.

In order to suppress an increase in the size of the power conversion device, a configuration in which the current sensor is formed integrally with other components is disclosed (for example, refer to Patent Document 1). The current sensor is constituted by a bus bar, a C-shaped core made of a magnetic material, and a magnetoelectric conversion element, the bus bar is disposed inside the C-shaped core, and the magnetoelectric conversion element is provided in a gap portion of the C-shaped core.

Since the above C-shaped core can be formed with a shorter gap length in the notch portion, an effect of the magnetic field concentration on the magnetoelectric conversion element can be enhanced. Therefore, the C-shaped core is often used as a magnetic core constituting the current sensor. The magnetoelectric conversion element is connected to a substrate and detects the magnetic flux generated in the notch portion due to a current flowing through the bus bar. The core includes a shield portion for reducing an influence of external magnetic fields on the magnetoelectric conversion element.

PRIOR ART DOCUMENT

### Patent Document

Patent Document 1: Japanese Patent No. 6372969

### SUMMARY OF THE INVENTION

### Problem to be Solved by the Invention

In the above Patent Document 1, since the side face portions of the C-shaped core are extended so that the extended portions face the bottom portion of the C-shaped core and the current sensor and the shield portions are integrally formed, it is possible to reduce the influence of external magnetic fields on the magnetoelectric conversion element while maintaining the effect of high magnetic field concentration by the C-shaped core, and to reduce the size of the power conversion device.

However, there is a problem in that the current detection accuracy of the power conversion device is reduced due to a position shift of the magnetoelectric conversion element provided on the substrate from a predetermined position in the gap portion of the core by an external force such as vibration. Further, as the power conversion device is downsized, a relative distance between electric components is reduced, and the influence of external magnetic fields on the gap portion of the core is increased, so that a problem arises in that the shield portion is increased in size in order to reduce the influence of the magnetic field from the outside.

Therefore, an object of the present application is to obtain a power conversion device that can improve the positioning accuracy of a magnetoelectric conversion element with respect to a gap portion of a core to improve the current detection accuracy and can reduce the influence of external magnetic fields on the gap portion of the core, while maintaining the effect of high magnetic field concentration by the core and the miniaturization of the power conversion device.

### Means for Solving the Problem

A power conversion device disclosed in the present application includes a substrate having one or more through holes, a bus bar connected to a power module and disposed to face the substrate, a core surrounding the bus bar, having a prismatic body with a notch portion, and including a pair of protruding portions formed along the notch portion, and a magnetoelectric conversion element disposed on the substrate and configured to convert a detected magnetic field into an electrical signal. At least one of the pair of protruding portions of the core is inserted into the one or more through holes and fixed to the substrate, and the magnetoelectric conversion element is disposed in either the notch portion of the core or a clearance between the pair of protruding portions of the core.

### Advantageous Effect of Invention

According to the power conversion device disclosed in the present application, the protruding portions of the core made of a magnetic material is inserted into one or more through holes provided in the substrate, and the magnetoelectric conversion element is disposed in a portion of the substrate in the vicinity of the through holes. Therefore, while maintaining an effect of high magnetic field concentration by the core, the core also serves as a positioning element with respect to the substrate. Therefore, it is possible to obtain a power conversion device that can improve the positioning accuracy of the magnetoelectric conversion element with respect to the gap portion of the core to improve the current detection accuracy, and reduce the influence of external magnetic fields on the gap portion of the core.

### BRIEF DESCRIPTION OF THE DRAWINGS

FIG. 1 is a schematic diagram showing a schematic configuration of a power conversion device according to Embodiment 1.

FIG. 2 is a perspective view showing a main part of the power conversion device according to Embodiment 1.

FIG. 3 is a front view showing the main part of the power conversion device according to Embodiment 1.

FIG. 4 is a front view for describing a current sensor of the power conversion device according to Embodiment 1.

FIG. 5 is the front view for describing a structure of the current sensor of the power conversion device according to Embodiment 1.

FIG. 6A is a plan view showing a main part of a power conversion device according to Embodiment 2.

FIG. 6B is a front view showing the main part of the power conversion device according to Embodiment 2.

FIG. 7 is a front view showing a main part of a power conversion device according to Embodiment 3.

FIG. 8 is a front view showing a main part of a power conversion device according to Embodiment 4.

FIG. 9 is a front view showing a main part of a power conversion device according to Embodiment 5.

### MODE FOR CARRYING OUT INVENTION

Hereinafter, power conversion devices according to embodiments of the present application will be described with reference to the drawings. In addition, in each of the drawings, the same or corresponding members and portions are denoted by the same reference numerals.

### Embodiment 1

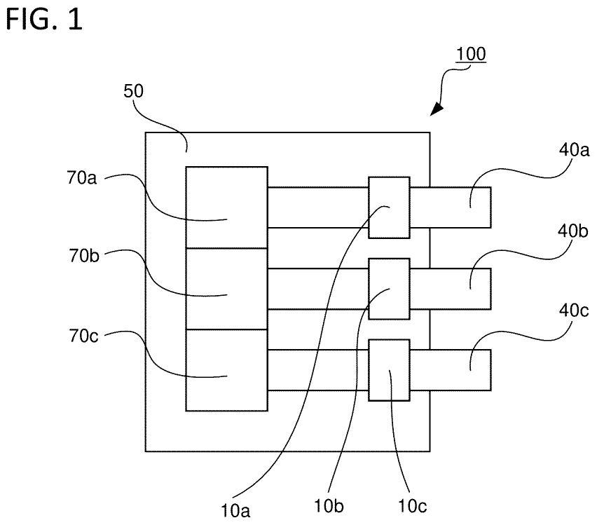

A power conversion device 100 that performs electric power conversion is used by being installed on a vehicle such as an electric automobile or a hybrid electric automobile that includes a motor as one of driving sources. The outline of a configuration of the power conversion device 100 will be first described below with reference to FIG. 1.

FIG. 1 is a schematic diagram showing the outline of the configuration of the power conversion device 100. FIG. 1 is also a view of the power conversion device 100 as viewed from the lower face side of a substrate 50 that is a main component.

As shown in FIG. 1, bus bars 40a, 40b, and 40c are respectively configured to penetrate the inside of cores 10a, 10b, and 10c each having a notch portion in the upper portion and each having a podium shape when viewed from the front, which respectively constitute current sensors 30a, 30b, and 30c (current sensors will be described in detail below) attached to the substrate 50 (bus bars and podium shaped cores will also be described in detail below), and are respectively connected to power modules 70a, 70b, and 70c included in the power conversion device 100.

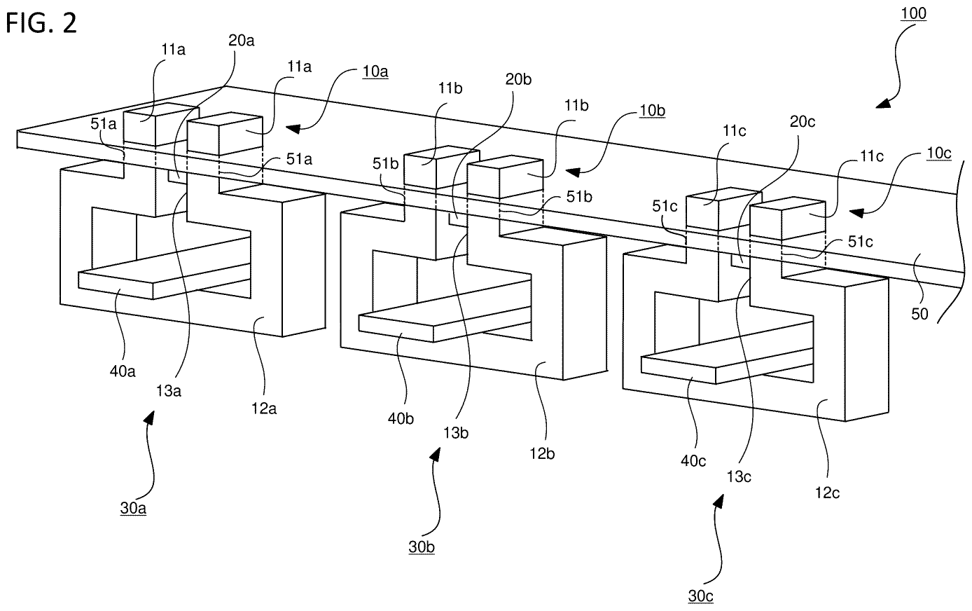

Note that, although the power modules 70a, 70b, and 70c are described above as being separate from each other, they may be integrated with each other. Next, a configuration of main parts of the power conversion device 100 will be described in detail below with reference to FIG. 2 to FIG. 5.

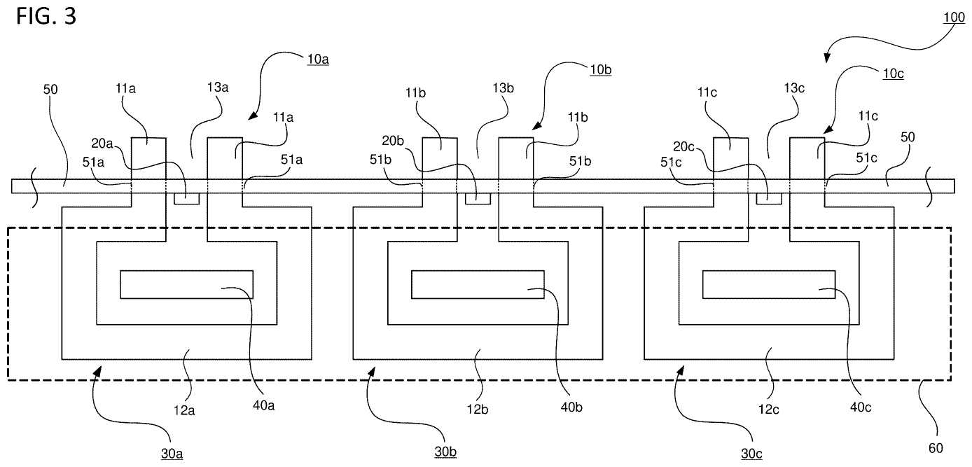

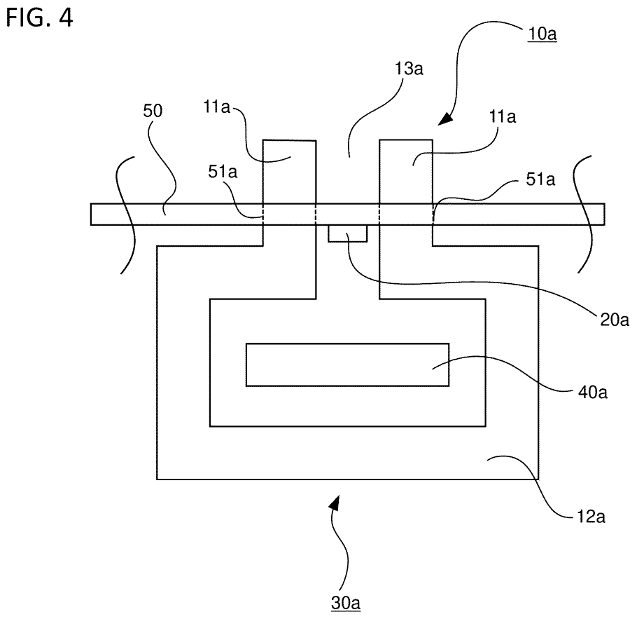

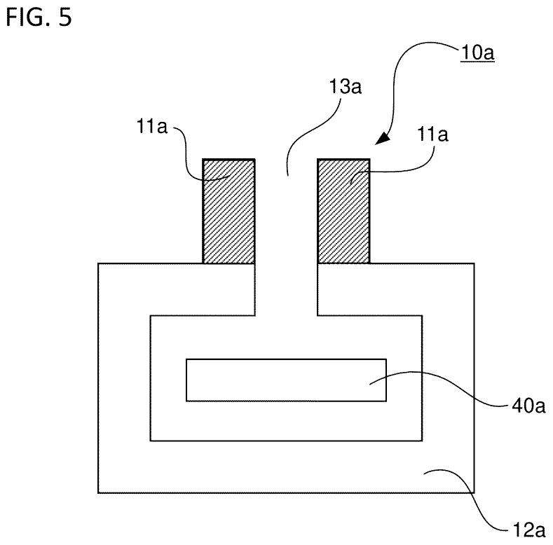

FIG. 2 is a perspective view showing the main parts of the power conversion device 100 according to Embodiment 1, and FIG. 3 is a front view showing the main parts of the power conversion device 100. Here, FIG. 2 and FIG. 3 are diagrams in a case where a housing surrounding the power conversion device 100 is removed from the entire configuration of the power conversion device 100. Further, FIG. 4 is a front view showing the current sensor 30a that is a main part of the power conversion device 100 of FIG. 2, and FIG. 5 is a front view showing the podium shaped core 10a that is a main part of the current sensor 30a of FIG. 4.

### <Configuration of Power Conversion Device >

The power conversion device 100 includes three flat plate-shaped bus bars 40a, 40b, and 40c through which three-phase electric currents flow each in its respective bus bar, as shown in FIG. 2 and FIG. 3. In addition, in order to measure each of current values of the three phase currents, the current sensor 40a is provided in the bus bar 30a, the current sensor 40b is provided in the bus bar 30b, and the current sensor 40c is provided in the bus bar 30c. Note that the bus bars 40a, 40b, and 40c have the same shape, and the current sensors 30a, 30b, and 30c have the same configuration as described below.

Further, the power conversion device 100 includes, in addition to the bus bars 40a, 40b, and 40c described above, the podium shaped cores 10a, 10b, and 10c that constitute the current sensors 30a, 30b, and 30c, and magnetoelectric conversion elements 20a, 20b, and 20C mounted on the surface of the substrate 50. Here, each of the cores is a prismatic body as a whole, and has the notch portion, and a pair of columnar bodies (hereinafter, also referred to as a pair of protruding portions) are disposed along the notch portion outward so as to face each other.

The three bus bars 40a, 40b, and 40c are conductors through which respective currents of three phases, i.e., a u-phase, a v-phase, and a w-phase flow. These three bus bars are made of, for example, copper or aluminum. However, the material is not limited to these, and other materials may be used as long as a current flows therethrough.

Further, as shown in FIG. 2 and FIG. 3, the core 10a, 10b, and 10c formed in the podium shape when viewed from the front of the device are made of a magnetic material, and, respectively, include cores 12a, 12b, and 12c formed in a C-shape when viewed from the front of the device, and a pair of protruding portions 11a, 11b, and 11c (hereinafter, also referred to as shield portions) in which end portions of the C-shaped core are extended in a direction opposite to the positions where the bus bars 40a, 40b, and 40c are installed.

Note that, in addition to the magnetoelectric conversion elements 20a, 20b, and 20c described above, passive components such as an integrated circuit (IC), a resistor, and a capacitor, and another necessary electric component that is, for example, a circuit that controls the operation of the power modules, are mounted on the substrate 50. The substrate 50 has the function of detecting the respective currents flowing through the bus bars 40a, 40b, and 40c by the magnetoelectric conversion elements 20a, 20b, and 20c.

The magnetoelectric conversion elements 20a, 20b, and 20c also detect external magnetic fields that are magnetic fields other than the magnetic fields generated due to the currents flowing through the bus bars 40a, 40b, and 40c to be measured. The external magnetic fields detected by the magnetoelectric conversion elements 20a, 20b, and 20c causes an error in the current measurement.

For example, when the object to be measured is the bus bar 40a, the magnetic field generated due to the current flowing through the adjacent bus bars 40b and 40c is one of the external magnetic fields. In order to measure the current with high accuracy, it is important to suppress the influence of the external magnetic fields. Therefore, it is desirable to dispose a magnetic sensitive portion of the magnetoelectric conversion element 20a at a predetermined position of a clearance 13a (hereinafter, also referred to as a gap portion 13a) formed inside the pair of the protruding portions 11a. Note that the same applies to the clearance 13b (hereinafter also referred to as a gap portion 13b) and the clearance 13c (hereinafter also referred to as a gap portion 13c).

Here, when the podium shaped core 10a concentrates the magnetic field generated due to the current flowing through the bus bar 40a, the efficiency of magnetic field concentration is inversely proportional to the size of the gap in the gap portion 13a. By reducing the size of the gap portion 13a, the efficiency of magnetic field concentration occurring at the core can be improved, and by disposing the protruding portions 11a closer to the magnetoelectric conversion element 20a, the influence of external magnetic fields can be minimized.

A surface-mounted magnetoelectric conversion element can be used in the power conversion device 100 of Embodiment 1. In this case, the magnetoelectric conversion elements are surface-mounted on the substrate 50. Note that the form of mounting the magnetoelectric conversion elements on the substrate 50 is not limited to the surface mounted type, but by using the surface mounted type magnetoelectric conversion elements, the influence of vibration on the magnetoelectric conversion elements is suppressed, and thus the accuracy of current detection of the power conversion device 100 can be improved.

Further, in Embodiment 1, as shown in FIG. 3 within a dotted line frame, a part of each of the podium shaped cores 10a, 10b, and 10c, and the bus bars 40a, 40b, and 40c are integrated by a resin 60.

When the multiple cores 10a, 10b, and 10c in the podium shape and the multiple bus bars 40a, 40b, and 40c are integrated by resin molding or the like, multiple components can be handled as a single component. In this way, since the multiple components can be handled as a single component, labor can be saved in the assembly and inspection processes, and the productivity of the power conversion device 100 can be improved.

Note that the podium shaped cores 10a, 10b, and 10c and the bus bars 40a, 40b, and 40c may be separately combined, and integrated with separate combinations by the resin 60 (for example, integration by a combination of the podium shaped core 10a and the bus bar 40a).

In Embodiment 1, as shown in FIG. 2, the current sensors 30a, 30b, and 30c are disposed along the edge of the substrate 50 (arrangement shifted toward front side), but the arrangement of the current sensors 30a, 30b, and 30c is not limited thereto. In addition, in a case where through holes 51a, 51b, and 51c are formed in the substrate 50, the podium shaped core 10a and the others can be disposed at the center of the substrate 50 instead of the edge thereof.

Therefore, in the power conversion device 100, the flexibility of the arrangement of the electric components and the current sensors 30a, 30b, and 30c mounted on the substrate 50 is improved, and the producibility of the power conversion device 100 can be improved.

In the above, the current sensor 30a is composed of the podium shaped core 10a and the magnetoelectric conversion element 20a, the current sensor 30b is composed of the podium shaped core 10b and the magnetoelectric conversion element 20b, and the current sensor 30c is composed of the podium shaped core 10c and the magnetoelectric conversion element 20c. As described above, in the power conversion device of Embodiment 1, the assembly errors of the respective magnetoelectric conversion elements 20a, 20b, and 20c with respect to the corresponding gap portions 13a, 13b, and 13c can be reduced. Specifically, since the pair of protruding portions of the above-described core are fixed to the through holes of the substrate, the podium shaped core and the substrate are integrally formed, and thus error factors such as dimensional tolerance can be reduced.

Note that the podium shaped cores 10a, 10b, and 10c all have the same shape, and each of them is attached in such a way that a portion of the core penetrates the substrate 50. Further, the magnetoelectric conversion elements 20a, 20b, and 20c all have the same shape and are disposed on the surface of the substrate 50 in the same manner. Therefore, in the following, the current sensor 30a will be taken as a representative example, and the configuration thereof will be described in more detail with reference to FIG. 4 and FIG. 5, which are the front views of the power conversion device as seen from the front.

### <Current Sensor >

As shown in FIG. 4, the current sensor 30a includes the podium shaped core 10a, the magnetoelectric conversion element 20a, and the bus bar 40a. As described above, the podium shaped core 10a is composed of the C-shaped core 12a and the protruding portions 11a, and as shown in FIG. 4, the end portions of the C-shaped core 12a and the protruding portions 11a are formed in a pair so as to face each other in a bilaterally symmetrical manner, and thus the clearance 13a (gap portion 13a) is formed. The magnetoelectric conversion element 20a is disposed on the surface of the substrate 50 in the gap portion 13a. Note that, in FIG. 4 and FIG. 5, the power conversion device is shown in a planar view, and therefore, in these figures, the core 10a is referred to as the podium shaped core 10a (the same applies hereinafter). In the above, the C-shaped core 12b and 12c respectively related to the core 10b and 10c shown in FIG. 2 and FIG. 3 have not been described in relation to FIG. 4, but these are also similar to the case of the C-shaped core 12a.

Here, since the substrate 50 has two through holes 51a on the left and right of the magnetoelectric conversion element 20a, that is, the magnetoelectric conversion element 20a is disposed on the surface of the substrate 50 between the two through holes 51a, and converts the detected magnetic field into an electric signal and outputs the electric signal. Note that, in FIG. 4, the magnetoelectric conversion element 20a is disposed not on both the front and rear surfaces of the substrate 50 but on only one of the surfaces of the substrate 50 facing the bus bar 40a.

Specifically, when the magnetoelectric conversion element 20a is disposed on one surface of the substrate 50, by disposing the magnetoelectric conversion element 40a on the surface (lower face in FIG. 4) of the substrate 50 closer to the bus bar 20a, the magnetoelectric conversion element 20a is less likely to be affected by the external magnetic fields. Therefore, the influence of the external magnetic fields that cause noise is reduced, and the SN ratio (ratio of signal/noise) can be increased, so that the accuracy of current detection of the power conversion device 100 can be improved.

Here, for example, a hall element or a magneto resistive (MR) element is used as the magnetoelectric conversion element 20a. Examples of the MR element include an anisotropic magneto resistive (AMR) element, a giant magneto resistive (GMR) element, and a tunnel magneto resistive (TMR) element, and any of these elements may be used. Note that the magnetoelectric conversion element 20a is not limited to these elements, and may be other elements as long as the elements have the function of converting a detected magnetic field into an electric signal and outputting the electric signal.

The mounting location of the magnetoelectric conversion element 20a is not limited to one surface of the substrate 50, and the magnetoelectric conversion element may be mounted on the other surface of the substrate 50. This is because, if the magnetoelectric conversion element 20a is disposed on the gap portion 13a of the podium shaped core 10a, the magnetic flux caused by the current flowing through the bus bar 40a can be detected.

On the other hand, as shown in FIG. 5, the podium shaped core 10a described above is integrally formed by the C-shaped core 12a and the protruding portions 11a (also referred to as the shield portions 11a because they have the shield function, and refer to the hatched portion in FIG. 5) that are made of a magnetic material, and the bus bar 40a is installed to penetrate the podium shaped core 10a.

In this case, as shown in FIG. 4, a pair of protruding portions 10a, which are leg portions of the podium shaped core 11a, are inserted into respective two through holes 51a located on the left and right in FIG. 4 and are disposed on the substrate 50. That is, the podium shaped core 10a, which is a component of the current sensor 30a, is provided integrally with the substrate 50, and the space is shared by both the podium shaped core 10a and the substrate 50, so that the height of the power conversion device 100 can be reduced in the direction perpendicular to the surface of the substrate 50, as compared with a substrate without the through holes 51a.

Further, since the protruding portions 11a, which is the leg portions of the podium shaped core 10a, is inserted into the through holes 51, the relative positional relationship between the gap portion 13a and the magnetoelectric conversion element 20a is not changed even when the magnetoelectric conversion element 20a is displaced in the vertical direction due to an external force such as vibration, and the relative positional relationship can be maintained.

Furthermore, since the shield portions 11a are disposed in the vicinity of the magnetoelectric conversion element 20a, the influence of external magnetic fields on the gap portion 13a can be reduced. This indicates that the current detection accuracy of the power conversion device 100 can be improved.

Note that, as the material of the podium shaped core 10a, for example, an electromagnetic steel sheet, steel, permalloy, or ferrite is used. These materials should be ferromagnetic materials such as iron, nickel, and cobalt, or materials containing ferromagnetic materials, and soft magnetic materials are particularly suitable. The method of manufacturing the podium shaped core 10a may be either that of a wound core or a laminated core.

Here, the magnetic field generated at the gap portion 13a due to the current flowing through the bus bar 40a reaches the magnetoelectric conversion element 20a. The main direction of the magnetic sensitivity (magnetic field vector) of the magnetoelectric conversion element 20a is parallel to the arrangement face of the substrate 50 on which the magnetoelectric conversion element 20a is disposed. The magnetoelectric conversion element 20a generates a voltage corresponding to the magnitude of the sensed magnetic field, converts the generated voltage into a current, and outputs an electric signal corresponding to the magnitude of the measured current to a circuit provided on the substrate 50.

Although an IC included in the magnetoelectric conversion element 20a is described as including a converter that converts the magnetic field into a current to convert the magnitude of the magnetic field into the value of the current, an IC different from the magnetoelectric conversion element 20a may include the converter and the different IC may be mounted on the substrate 50.

### Embodiment 2

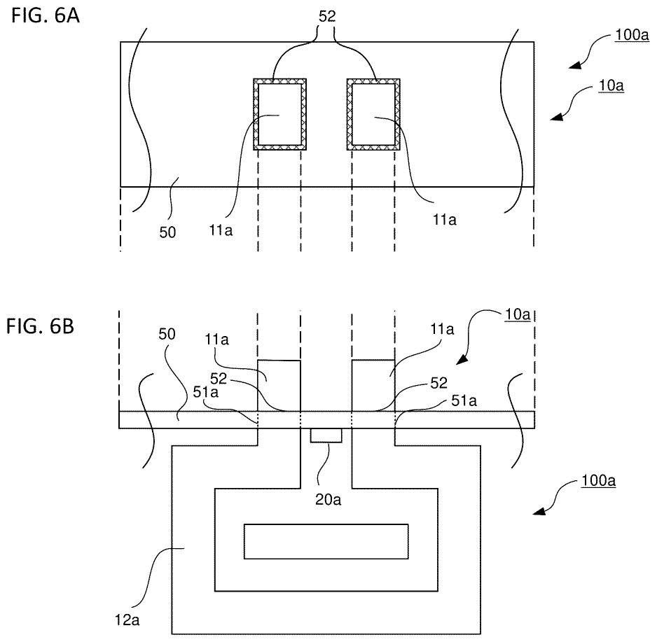

A power conversion device 100 a according to Embodiment 2 will be described below with reference to the drawings. FIG. 6A and FIG. 6B are a plan view (upper side) and a front view (lower side), respectively, showing one current sensor 30a constituting a main part of a power conversion device 100 a according to Embodiment 2.

In the power conversion device 100 a according to Embodiment 2, in addition to the configuration shown in Embodiment 1, the shield portions 11a, which are two leg portions of the podium shaped core 10a constituting the gap portion 13a, is inserted into two through holes 51a provided in the substrate 50, and an adhesive 52 is applied to (gaps) of boundary portions between the two leg portions of the podium shaped core 10a and the through holes 51a.

In FIG. 6A, since the shield portions 11a, which are the two leg portions of the podium shaped core 10a, and the two through holes 51a provided in the substrate 50 are fixed by the adhesive 52, the relative displacement amount between the gap portions 13a and the predetermined position of the magnetoelectric conversion element 20a due to an external force such as vibration can be reduced. Therefore, the accuracy of current detection of the power conversion device 100a can be improved.

### Embodiment 3.

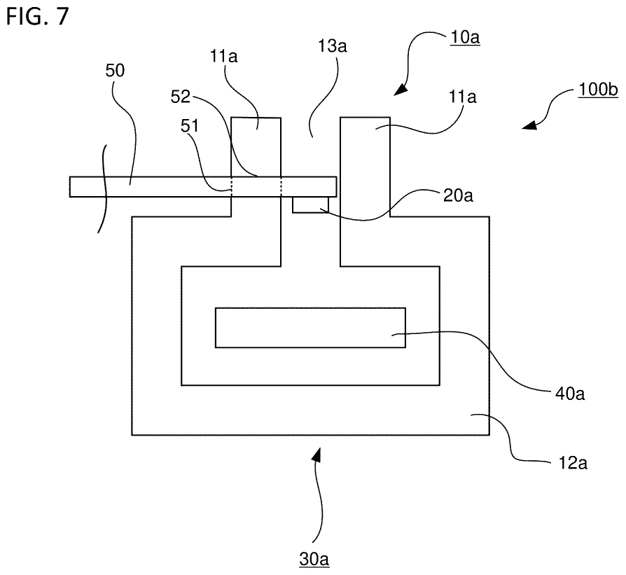

A power conversion device 100 b according to Embodiment 3 will be described below with reference to the drawings. FIG. 7 is a front view showing one current sensor 30a that is a main part of a power conversion device 100 b according to Embodiment 3.

The power conversion device 100 b according to Embodiment 3 has a different configuration from the configurations of the power conversion devices shown in Embodiment 1 and Embodiment 2, and has the configuration in which one of the two leg portions of the podium shaped core 10a is inserted into one through hole 51a provided in the substrate 50 and is disposed on the substrate 50.

Specifically, in FIG. 7, of the two shield portions 11a of the podium shaped core 10a, the shield portion located on the left (hereinafter, also referred to as the left leg portion) is inserted into the through hole 51 and disposed on the substrate 50. Even when an external force such as vibration is generated, the left leg portion of the podium shaped core 10a and the through hole 51 can maintain the relative positional relationship between the position of the gap portion 13a and the position of the magnetoelectric conversion element 20a against the external force such as vibration, and thus the accuracy of current detection of the power conversion device 100 can be improved as compared with the case where there exists the influence of external force such as vibration. Further, since the shield portions 11a are disposed in the vicinity of the magnetoelectric conversion element 20a, the influence of external magnetic fields on the magnetoelectric conversion element 20a due to the positional change of the gap portion 13a can be reduced.

### Embodiment 4

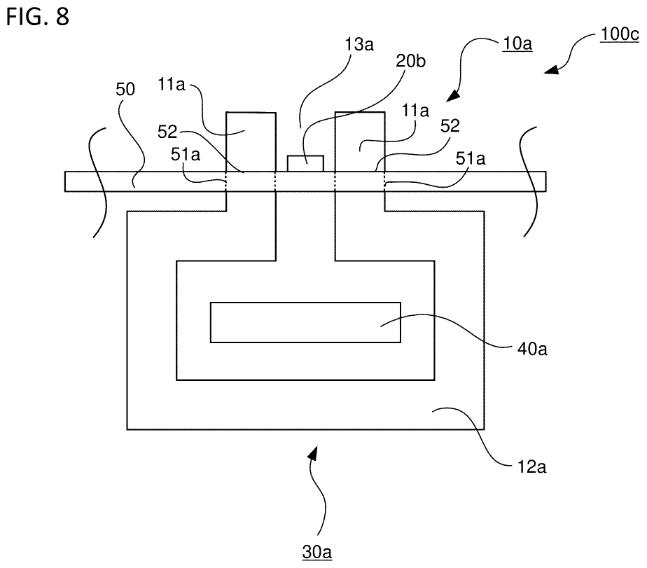

A power conversion device 100 c according to Embodiment 4 will be described below with reference to the drawings. FIG. 8 is a front view showing one current sensor 30a that is a main part of a power conversion device 100 c according to Embodiment 4. The power conversion device 100 c according to Embodiment 4 has a different configuration from the configurations shown in Embodiment 1 and Embodiment 2 in that the magnetoelectric conversion element is disposed on the upper surface of the substrate 50 on the side farther from the bus bar.

In FIG. 8, since the gap portion 13a of the podium shaped core 10a is configured to penetrate the substrate 50 on which the magnetoelectric conversion element is disposed, the magnetoelectric conversion element 20b can be disposed on either the upper surface or the lower surface of the substrate 50. When a current is applied to the bus bar 40a, the temperature of the bus bar 40a rises. In this case, since the magnetic field detection accuracy of the magnetoelectric conversion element 20b changes due to the influence of temperature change, the influence of temperature change from the bus bar 40a can be reduced more in the case where the magnetoelectric conversion element is disposed on the surface of the substrate 50 on the side farther from the bus bar 40a than in the case where the magnetoelectric conversion element is disposed on the surface of the substrate 50 on the side close to the bus bar 40a.

If there exist electronic components or patterns other than the magnetoelectric conversion element 20b in the gap portion 13a, they generate magnetic fields, and thus, act to prevent the magnetic flux from the bus bar 40a in the magnetic field concentration path including the gap portion 13a, thereby reducing the detection accuracy of the current flowing through the bus bar 40a. Therefore, electronic components other than the magnetoelectric conversion element 20b are not disposed in the gap portion 13a as much as possible.

When the magnetoelectric conversion element 20a is disposed as the magnetoelectric conversion element 20b on the surface of the substrate 50 on the side farther from the bus bar 40a as in the power conversion device 100 c of Embodiment 4, the influence of the temperature change from the bus bar 40a can be reduced, and thus the detection accuracy of the current flowing through the bus bar 40a can be improved.

### Embodiment 5

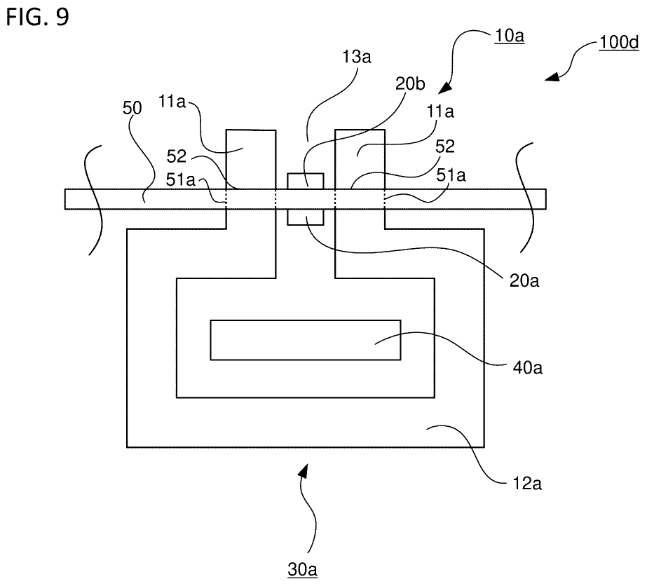

A power conversion device 100 d according to Embodiment 5 will be described below with reference to the drawings. FIG. 9 is a front view showing one current sensor 30a that is a main part of a power conversion device 100 d according to Embodiment 5. The power conversion device 100 d according to Embodiment 5 has a different configuration from the configurations shown in Embodiment 1 and Embodiment 2 in that two magnetoelectric conversion elements 20a and 20b are disposed on both the surfaces of the substrate 50.

In FIG. 9, the gap portion 13a of the podium shaped core 10a is inserted into the through holes 51a of the substrate 50, and thus the magnetoelectric conversion elements 20a and 20b can be disposed on both the surfaces of the substrate 50. By disposing the magnetoelectric conversion element 20a and the magnetoelectric conversion element 20b on the lower surface and the upper surface of the substrate 50, respectively, the current detection function of the current sensor 30a can be made redundant.

For example, when the magnetoelectric conversion element 20a disposed on one surface of the substrate 50 is a main and the magnetoelectric conversion element 20b disposed on the other surface is a sub, a value obtained from the magnetoelectric conversion element 20a is acquired as the current detection value during a normal operation. If the magnetoelectric conversion element 20a is short-circuited to the power supply or the ground, or has another failure, a comparison with the value of the sub magnetoelectric conversion element 20b, which is disposed on the other surface of the substrate 50, makes it possible to determine whether a failure has occurred in the magnetoelectric conversion element 20a. Note that, as the division of roles between the main and sub magnetoelectric conversion elements above, either the magnetoelectric conversion element 20a or 20b can be designated as the main element.

Although various exemplary embodiments and examples are described in the present application, various features, aspects, and functions described in one or more embodiments are not inherent in an application of the contents disclosed in a particular embodiment, and can be applicable alone or in their various combinations to each embodiment. Accordingly, countless variations that are not illustrated are envisaged within the scope of the art disclosed in the specification of the present application. For example, the case where at least one component is modified, added or omitted, and the case where at least one component is extracted and combined with a component disclosed in another embodiment are included. Specifically, the power conversion devices according to Embodiment 1 to Embodiment 5 can be installed and used in various electric vehicles, for example, a hybrid electric vehicle or a battery electric vehicle (EV in general name). In this case, in power conversion devices installed in the electric vehicles, the speed in the control thereof is getting faster in order to improve output accuracy. However, the faster the control, the higher the noise level tends to be. Therefore, the present power conversion device capable of improving the current detection accuracy by reducing the influence of external magnetic fields is particularly useful.

### DESCRIPTION OF REFERENCE NUMERALS AND SIGN

10a, 10b, 10c: core, 11a, 11b, 11c: protruding portion (shield portion), 12a, 12b, 12c: C-shaped core, 13a, 13b, 13c: gap portion (clearance), 20a, 20b, 20c: magnetoelectric conversion element, 30a, 30b, 30c: current sensor, 40a, 40b, 40c: bus bar, 50: substrate, 51, 51a, 51b, 51c: through hole, 52: adhesive, 60: resin, 70a, 70b, 70c: power module, 100, 100a, 100b, 100c, 100d: power conversion device

1. A power conversion device comprising:
a substrate having one or more through holes;
a bus bar connected to a power module and disposed to face the substrate;
a core surrounding the bus bar, having a prismatic body with a notch portion, and including a pair of protruding portions formed along the notch portion; and
a magnetoelectric conversion element disposed on the substrate and configured to convert a detected magnetic field into an electrical signal, wherein
at least one of the pair of protruding portions of the core is inserted into the one or more through holes and fixed to the substrate, and
the magnetoelectric conversion element is disposed in either the notch portion of the core or a clearance between the pair of protruding portions of the core.

2. The power conversion device according to claim 1, wherein the protruding portions and the one or more through holes are fixed to each other with an adhesive.

3. The power conversion device according to claim 1, wherein the core and the bus bar are integrated with resin.

4. The power conversion device according to claim 1, wherein the magnetoelectric conversion element is disposed on at least one surface of the substrate facing the bus bar.

5. The power conversion device according to claim 1 or 2, wherein the magnetoelectric conversion element is surface-mounted on the substrate.

6. The power conversion device according to claim 1, wherein the substrate includes a circuit that controls an operation of the power module.

7. An electric vehicle comprising the power conversion device according to claim 1.

8. The power conversion device according to claim 2, wherein the core and the bus bar are integrated with resin.

9. The power conversion device according to claim 2, wherein the magnetoelectric conversion element is disposed on at least one surface of the substrate facing the bus bar.

10. The power conversion device according to claim 2, wherein the magnetoelectric conversion element is surface-mounted on the substrate.

11. The power conversion device according to claim 2, wherein the substrate includes a circuit that controls an operation of the power module.

12. The power conversion device according to claim 3, wherein the substrate includes a circuit that controls an operation of the power module.

13. The power conversion device according to claim 4, wherein the substrate includes a circuit that controls an operation of the power module.

14. The power conversion device according to claim 5, wherein the substrate includes a circuit that controls an operation of the power module.

15. The power conversion device according to claim 8, wherein the substrate includes a circuit that controls an operation of the power module.

16. The power conversion device according to claim 9, wherein the substrate includes a circuit that controls an operation of the power module.

17. The power conversion device according to claim 10, wherein the substrate includes a circuit that controls an operation of the power module.

18. An electric vehicle comprising the power conversion device according to claim 2.

19. An electric vehicle comprising the power conversion device according to claim 3.

20. An electric vehicle comprising the power conversion device according to claim 4.
